(19) United States
(12) Patent Application Publication
(10) Pub. No.: US 2008/0042637 A1
(43) Pub. Date: Feb. 21, 2008

(54) Magnetic toroid self resonant current sensor

(75) Inventors: David A. Sandquist, St. Paul, MN (US); Dale F. Berndt, Plymouth, MN (US); Andrzej Peczalski, Eden Prairie, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/506,339

(22) Filed: Aug. 18, 2006

(51) Int. Cl. G01R 15/18

(52) U.S. Cl. 324/117 R

(57) ABSTRACT

A current sensor includes a transformer comprising a primary and a secondary, wherein the current sensor is operable to measure current in the primary. A sensing circuit is operable to detect an impedance of the secondary, where the impedance of the secondary changes with an amount of current in the primary and is used to indicate the current in the primary.

### FIELD OF THE INVENTION

The invention relates generally to current sensing, and more specifically to a magnetic toroid self-resonant current sensor.

### BACKGROUND

When electricity flows through a conductive medium, the amount of electric charge that flows in a period of time can be expressed as electrical current. Using standard units, when a coulomb of electrons flows through a conductor in a second, the conductor is said to be carrying an amp or an ampere of current, where one coulomb is equal to the electrical charge of approximately 6.24×10̂18 electrons, or 6.24 quintillion electrons. Similarly, half a coulomb per second would be expressed as a current of 500 milliamps, and ten coulombs every two seconds would be expressed as five amps.

Measurement of electrical current is somewhat difficult in that many of the simplest methods to measure electrical current, such as measuring the voltage drop across a known resistance placed in series with the conductor, can significantly affect the signal being measured. Even less intrusive current measurement methods such as using a conductive loop around a wire to measure induced voltage or current has a small transformer effect drain on the conductor, and are subject to inaccuracies from stray electric or magnetic field interference, limited bandwidth due to the inductance of the current sensing loop or loops, and other effects.

Electrical current sensors are used in a variety of industrial applications, control systems, and even in common electronic devices, which require both high accuracy and small size. Further, the cost of current sensors for mass-produced products such as control systems is important to the commercial viability of the sensor, and of the product that incorporates current sensing functions.

Design of a current sensor will therefore consider a variety of factors, including the effect the current sensor has on the electrical signal being measured, the size and cost of the current sensor, the current sensor's accuracy, and immunity from stray electric fields or other forms of interference.

### SUMMARY

One example embodiment of the invention comprises a current sensor comprising a transformer having a primary and a secondary, and a sensing circuit. The sensing circuit is operable to detect an impedance of the secondary, where the impedance of the secondary changes with an amount of current in the primary and is used to indicate the current in the primary.

### BRIEF DESCRIPTION OF THE FIGURES

FIG. 1 shows a toroidal transformer, as may be used to practice some embodiments of the invention.

FIG. 2 is a chart showing impedance v. frequency of the secondary for various primary current levels, consistent with an example embodiment of the invention.

FIG. 3 illustrates the delay in observed current with application of a voltage step to the secondary of a transformer, consistent with an example embodiment of the invention.

FIG. 4A is a simplified schematic of a circuit operable to practice some example embodiments of the invention.

FIG. 4B is a timing diagram illustrating measurement of rise and fall delay times in a secondary, consistent with some example embodiments of the invention.

FIG. 4C shows rise delay and fall delay in the secondary v. current in the primary, as may be used to practice various embodiments of the invention.

FIG. 5 is a detailed schematic of a circuit consistent with an example embodiment of the invention.

### DETAILED DESCRIPTION

In the following detailed description of example embodiments of the invention, reference is made to specific example embodiments of the invention by way of drawings and illustrations. These examples are described in sufficient detail to enable those skilled in the art to practice the invention, and serve to illustrate how the invention may be applied to various purposes or embodiments. Other embodiments of the invention exist and are within the scope of the invention, and logical, mechanical, electrical, and other changes may be made without departing from the subject or scope of the present invention. Features or limitations of various embodiments of the invention described herein, however essential to the example embodiments in which they are incorporated, do not limit other embodiments of the invention or the invention as a whole, and any reference to the invention, its elements, operation, and application do not limit the invention as a whole but serve only to define these example embodiments. The following detailed description does not, therefore, limit the scope of the invention, which is defined only by the appended claims.

One example embodiment of the invention provides a current sensor comprising a transformer having a primary and a secondary, and a sensing circuit. The sensing circuit is operable to detect an impedance of the secondary, where the impedance of the secondary changes with an amount of current in the primary and is used to indicate the current in the primary. In a further embodiment, the impedance of the secondary is sensed by observing delay in current change when an electrical voltage signal applied to the secondary changes, such as by feeding an inverted signal from the secondary back into the secondary via a closed loop feedback connection and observing an oscillation frequency of the closed loop to measure the current in the primary.

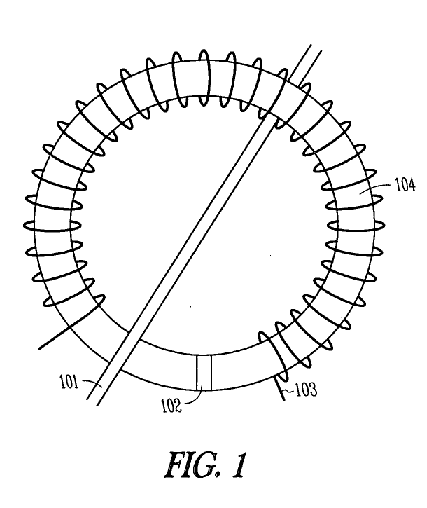

FIG. 1 is a diagram of a toroidal transformer, consistent with some example embodiments of the invention. A primary winding in this example is shown at 101, and is simply a straight wire inserted into the toroid, either by original configuration or by bringing the wire through a gap in the toroid material as shown at 102. A secondary winding 103 is also wrapped around the toroid-shaped transformer core 104, which is in some embodiments a high-permeability magnetic material that efficiently conducts magnetic flux. The primary winding is by custom the winding that is powered, but in various applications the primary, the secondary, or both windings can be driven with various electrical signals.

Although transformers such as the toroidal transformer of FIG. 1 are often used to step a voltage signal present in the primary up or down to another voltage that can be drawn off the secondary, the change in voltage realized between the primary and secondary in a transformer is also proportional to the change in current available, excluding minor transformer losses. For example, if the single-winding primary 101 were energized with five volts, 2000 volts would be observed on the 400-turn secondary winding 103, but with a maximum of approximately 1/400^{th} the current available.

This effect is used to measure current in the primary in some embodiments by inserting a hall effect sensor in the toroid gap 102 and measuring the magnetic flux in the transformer core as a current signal provided to the secondary winding is varied. As the current in the 400-turn secondary reaches 1/400^{th} the current present in the primary, the magnetic flux observed in the hall effect sensor is brought to zero or very nearly zero, and the known current supplied to the secondary can be used to calculate the current present in the primary.

This method in some embodiments uses a resistor in series with the current signal provided to the secondary, such that the voltage drop across the resistor can be measured to exactly determine the current flowing through the resistor and through the secondary. This voltage signal is converted to a digital signal value by an analog-to-digital converter, and read by a digital controller or other digital circuitry in typical applications. But this method has disadvantages, including the complexity and cost of the analog-to-digital converter and the control circuit.

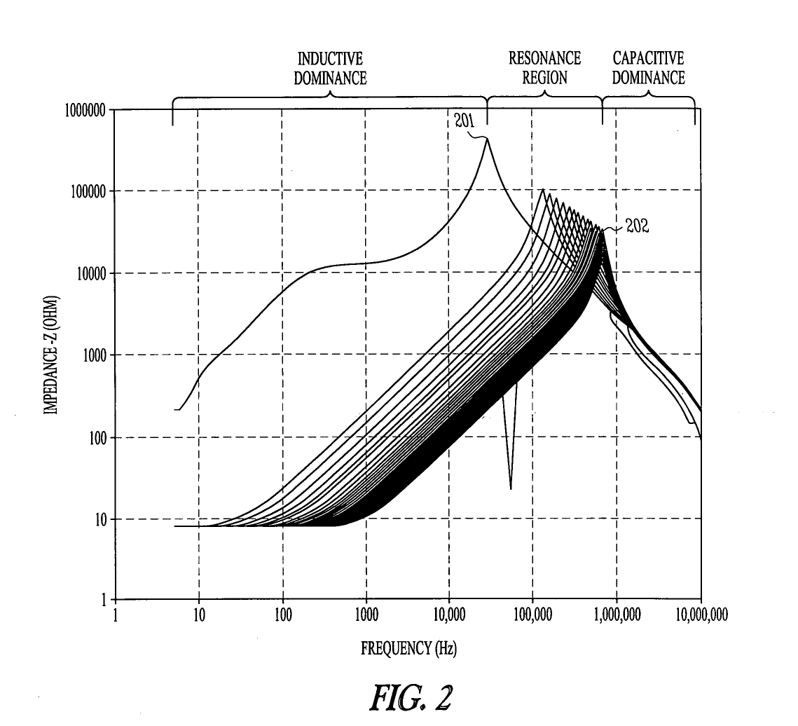

FIG. 2 is a graph showing impedance v. frequency curves observed in the secondary of a toroidal transformer such as that of FIG. 1 at various primary current levels, consistent with an example embodiment of the invention. The curve at 201 shows the relationship between frequency and impedance of the secondary winding with no current flowing through the primary. As frequency increases, the impedance increases, until a resonant frequency of approximately 28 kHz is reached. At frequencies higher than the resonant frequency, the impedance begins to drop again. A variety of similar impedance v. frequency curves are shown for different current levels, up to curve 202 which shows impedance v. frequency in the secondary with a current level of 10.2 amps in the primary. Not only has the resonant frequency increased from 28 kHz to 701 kHz, but the observed impedance at any given frequency below the secondary's zero current resonant frequency is lower than the observed impedance of the secondary with no current in the primary.

Current in the primary is therefore observable in several ways, including detection of the resonant frequency of the secondary, measuring the impedance of the secondary at a given frequency, or measuring the frequency at which a given secondary impedance is observed.

In one such embodiment, a fixed frequency is chosen based on the impedance characteristics of the secondary and the desired current sense range. Using the example curves of FIG. 2, frequencies above 28 kHz are not desired because the impedance of the secondary with no current has already reached its peak and will begin to drop as higher frequencies are selected. Also, at frequencies below 500 Hz there is little difference in impedance observed in the secondary between curves for the primary carrying 10 amps and 10.2 amps. Appropriate sense frequencies therefore appear to be in the approximate range of 800-25,000 Hz.

The impedance of the secondary winding can be observed as a delay in current in the secondary when a voltage change is applied to the secondary. The delay is related to the impedance of the secondary, including the inductance of the secondary as well as its resistance or any resistance in series with the secondary winding. This delay is also proportional to the size of the voltage step applied to the secondary, as a larger applied voltage will cause more current to flow more quickly, saturating the transformer core with magnetic flux which in turn promotes still greater current flow in the primary.

In one embodiment of the invention, this core saturation is controlled by monitoring the current flowing through a resistor and providing feedback to the signal provided to the secondary, such as by using the voltage across the resistor to trigger a comparator, which in turn is used to switch or invert the signal provided to the secondary winding. This creates a closed-loop feedback system that oscillates or changes state at a rate dependent on the impedance of the secondary, and therefore dependent on the amount of current flowing in the primary.

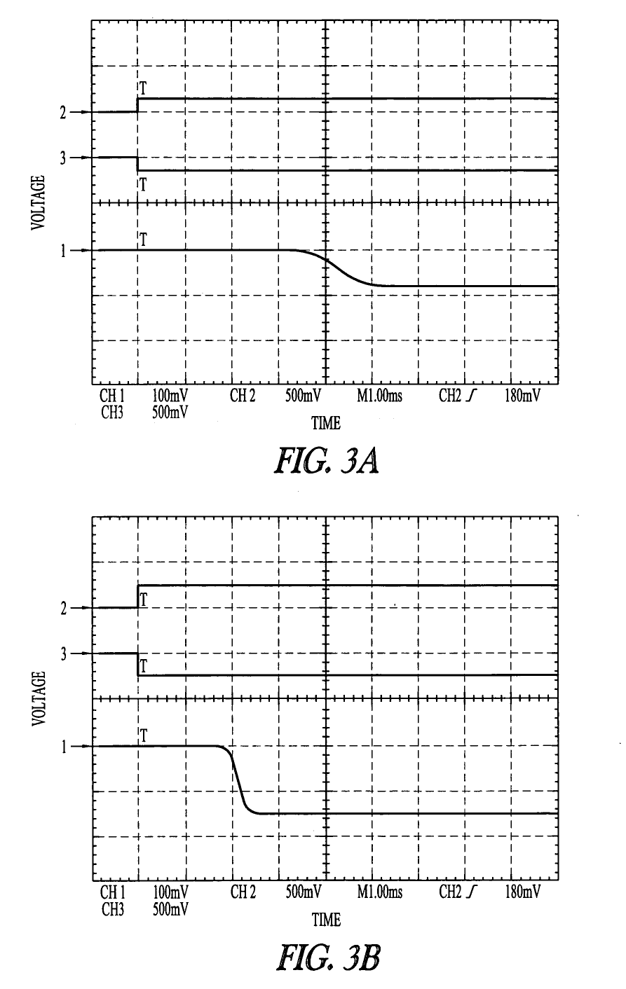

FIG. 3 illustrates a variety of secondary current response signals resulting from a change in voltage applied to the secondary, consistent with some embodiments of the invention. FIG. 3A shows a 0.125 volt square wave step applied at trace 2, and the time it takes to see a change in the voltage observed across a series load resistor, indicating current flow. Here, the change in current flow is approximately 80 mV/10 Ohms, or 8 mA, and occurs four to five seconds after the change in the voltage applied to the secondary. FIG. 3B shows how a larger voltage step of 0.25 volts results in twice the observed current change, and how the current flow change occurs around two milliseconds after the input voltage signal is changed rather than the approximately four second delay seen in FIG. 3A. This shows how the observed current change is larger with a larger applied voltage step, and how the observed resulting current change's delay after the applied voltage step varies with the voltage step applied. FIG. 3C shows yet a third example in which a 0.5 volt step signal is applied to the secondary, resulting in approximately twice the observed current change occurring with approximately half the delay observed in FIG. 3B's 0.25 volt step signal example. FIG. 3D is a rescaled version of FIG. 3C, showing how the change in current flowing through the secondary of the transformer increases more rapidly over time, as the transformer core becomes saturated with magnetic flux.

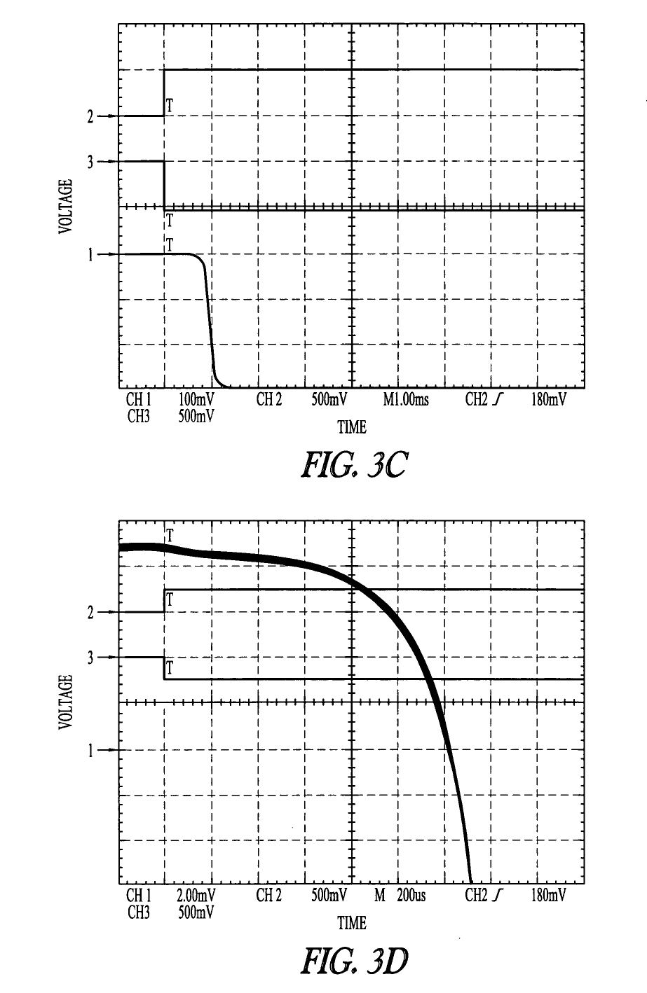

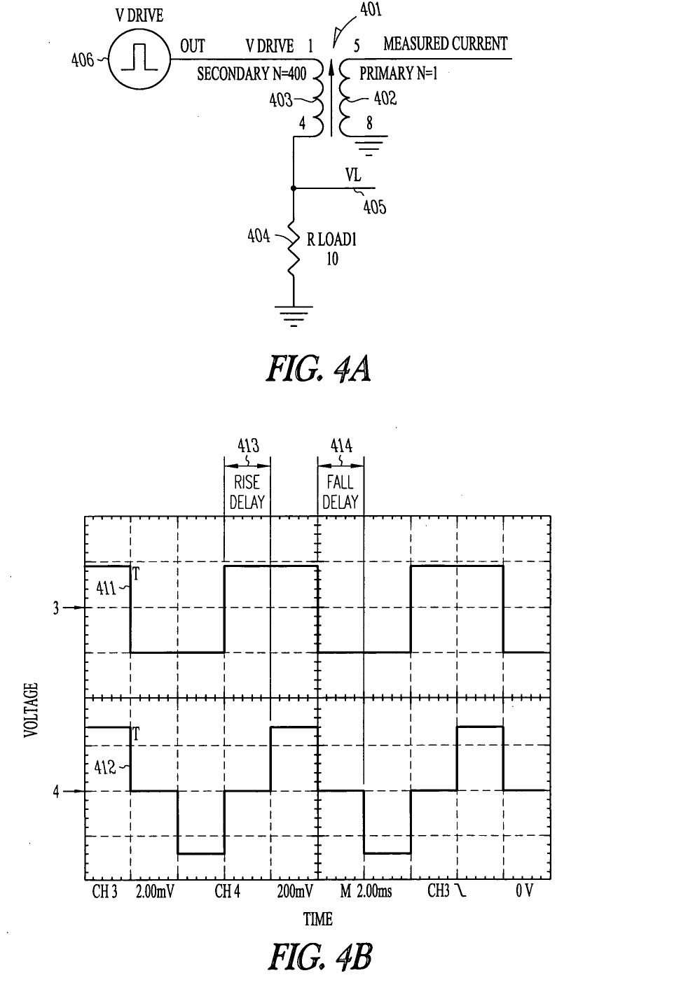

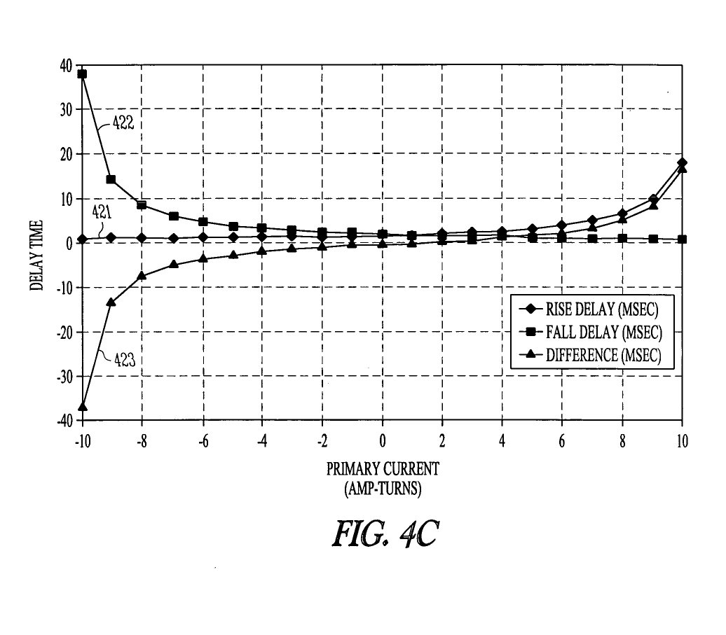

FIG. 4 shows a simplified system for sensing current delay to measure primary current, consistent with an example embodiment of the invention. FIG. 4A shows a schematic, illustrating an example configuration for measuring current in the primary of a transformer. A toroidal transformer 401 has a primary 402 which is a single winding, and a secondary 403 of 400 windings. The primary carries a current and is typically a part of another circuit being measured, or is part of a circuit using current measurement or feedback control as part of the circuit. The secondary 403 is connected to ground on one side via a load resistor 404, which in this embodiment is a 10 Ohm resistor including voltage drop measurement lead 405. The other side of the primary is fed a voltage signal by voltage source 406, which in this example is a square wave of pulses as shown at FIG. 4B.

The voltage v. time chart of FIG. 4 shows how with an applied square wave signal 411, the observed voltage across load resistor 404, and therefore the current flowing through the secondary 403, is delayed as shown by curve 412. When the square wave signal 411 provided to the secondary as shown at 406 changes from a lower voltage to a higher voltage, there is a delay in the current change as shown in curve 412. The time between the change in the square wave source and the observed current change is the rise delay, as shown at 413. Similarly, when the square wave signal 411 provided to the secondary changes state from a high voltage level to a low voltage level, the delay in change in current is observed as the fall delay shown at 414.

This pattern of rising and falling delays can be observed to measure the impedance of the secondary, and therefore the current flowing through the primary in some embodiments of the invention. But, the rising and falling delays seen in FIG. 4B are not symmetric, and in this example the delay observed for a positive current change is generally shorter than the delay observed for a falling current change. This is shown in greater detail in FIG. 4C, which illustrates how the observed rise and fall delays change with varying amounts of current present in the transformer primary.

At zero primary current, the rise time shown by curve 421 and fall time shown by curve 422 are approximately the same, with a difference between them as shown by curve 423 of approximately zero milliseconds. As current in the primary increases to positive values, the core material of the transformer becomes saturated with magnetic flux, driving its relative permeability down from very high values such as 10,000 to eventually approach the permeability of air at one. When an additional current is added to the secondary, it results in even greater saturation of the core if the current induces a magnetic field in the same direction as the primary induced field, and at very high primary currents takes relatively little time to show up as a change in observed current in the secondary. This can be seen in FIG. 4C by observing that the fall delay becomes increasingly shorter as the current in the primary increases, just as the rise delay becomes increasingly shorter as the current in the primary decreases.

Although the rise time and fall time curves 421 and 422 have opposite slopes and have the same value at or very near zero amps in the primary, the difference between the rise time and fall time delays relative to primary current as shown by curve 423 is a continuously rising smooth curve. This difference curve represents the duty cycle of the observed output pulse, which is simply the difference in time between time spent in one state and time spent in another state. The difference between rise time and fall time can therefore be observed to indicate the amount of current in the primary.

To generate an output signal having the desired duty cycle, the observed delayed change in current in the secondary can be inverted and fed back to the secondary as a change in state of the input signal 411, creating a self-oscillating system having a duty cycle and oscillation frequency dependent on the delay times 413 and 414, and therefore dependent on the current in the primary. The duty cycle can be easily tracked using digital electronics such as common processors or controllers, eliminating the need for an analog-to-digital converter to sense current in a digital system.

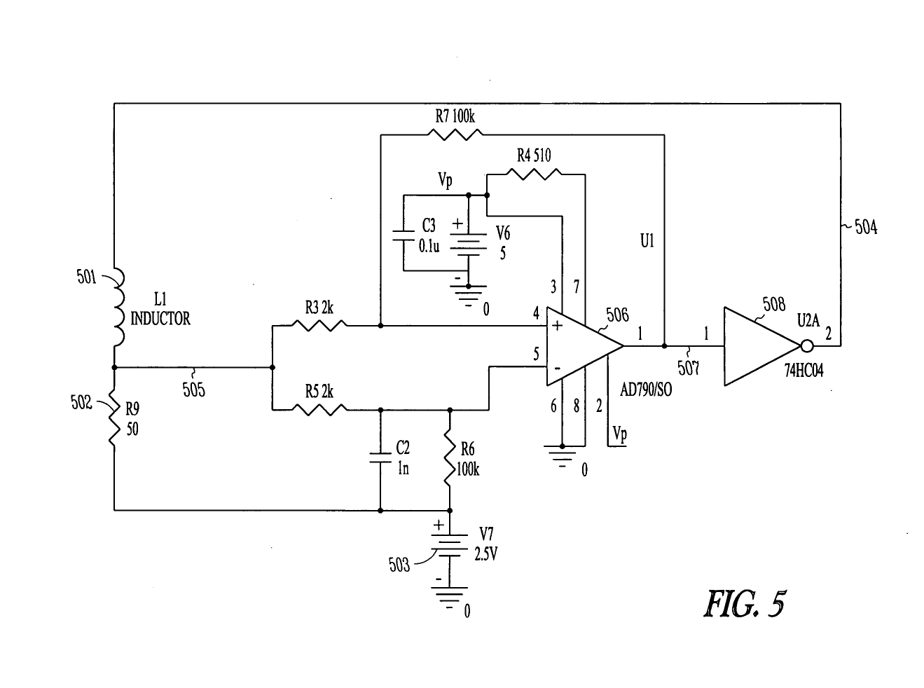

FIG. 5 shows a schematic of an example current sensing circuit, consistent with an example embodiment of the invention. Secondary winding 501 is coupled to a load resistor 502, which is a 50 Ohm load resistor coupled to a reference voltage of 2.5 volts as shown at 503. The secondary is driven with a feedback signal 504, and the current across output resistor 502 is measured as a voltage drop across the resistor at 505, which is an input to comparator circuit 506. The comparator changes the state of output signal 507 depending on whether the observed voltage at 505 is above or below the 2.5 volt reference voltage, configured as a Schmitt trigger to reduce switching near the threshold point due to noise. Capacitors also provide highpass and lowpass filtering of the inputs, creating a bandpass-type response for the Schmitt trigger to improve immunity to DC signals and high frequency noise.

In operation, the signal provided to the secondary 501 drives the core into saturation and current flow changes, resulting in a change of state of the comparator 506. This change in output state is inverted by inverter 508, resulting in a change of state of the input signal 504 provided to the secondary winding 501. The constant cycling of the signal 504 occurs with a frequency and a period dependent on the rise and fall delays of the inductor, which as noted in FIG. 4 and the accompanying description changes with current present in the primary. A digital processor can therefore easily count the number of clock cycles that output signal 504 is in each of its two states during oscillation of the feedback circuit of FIG. 5, and convert the observed duty cycle of the output signal to a known corresponding primary current level using methods such as an algorithm or a lookup table describing the relationship between duty cycle of a particular configuration and primary current.

These examples show how changes in the electrical characteristics of a transformer secondary as a result of current in the transformer's primary can be used to sense or measure the current in the secondary. A variety of other configurations and methods are within the scope of this invention, which is not limited by these examples. Although specific embodiments have been illustrated and described herein, it will be appreciated by those of ordinary skill in the art that any arrangement that achieve the same purpose, structure, or function may be substituted for the specific embodiments shown. This application is intended to cover any adaptations or variations of the example embodiments of the invention described herein. It is intended that this invention be limited only by the claims, and the full scope of equivalents thereof.

1. A current sensor, comprising:
a first transformer comprising a primary and a secondary wound around the same core, wherein the current sensor is operable to measure current in the primary; and
a sensing circuit coupled to the secondary and operable to detect a permeability of the core, wherein the permeability of the core changes in response to a change in current in the primary and is used to measure current in the primary.

2. The current sensor of claim 1, wherein the transformer comprises a magnetic toroidal core.

3. The current sensor of claim 1, wherein the permeability of the core is sensed by observing delay in current change when an electrical voltage signal applied to the secondary changes.

4. The current sensor of claim 3, wherein the electrical current change signal observed in the secondary is fed back into the secondary via a closed loop feedback connection.

5. The current sensor of claim 4, wherein an oscillation frequency of the closed loop feedback is used to measure the current in the primary.

6. The current sensor of claim 5, wherein the sense frequency is below the lowest resonant frequency of the secondary.

7. The current sensor of claim 5, wherein the feedback connection comprises a voltage pulse feedback signal.

8. The current sensor of claim 5, wherein the feedback connection comprises a comparator.

9. The current sensor of claim 8, wherein the feedback connection further comprises an inverter coupled to an output of the comparator.

10. A method of sensing electrical current, comprising:
detecting permeability of the core of a transformer having a primary and a secondary wound around the core by monitoring an electrical signal on the secondary, where permeability of the transformer core indicates an amount of current in the primary.

11. The method of claim 10, wherein the permeability of the core is sensed by observing delay in current change when an electrical voltage signal applied to the secondary changes.

12. The method of claim 10, further comprising feeding the electrical current change signal observed in the secondary back into the secondary via a closed loop feedback connection.

13. The method of claim 12, further comprising inverting the electrical current change signal fed back into the secondary.

14. The method of claim 13, wherein an oscillation frequency of the closed loop feedback is used to measure the current in the primary.

15. The method of claim 14, wherein the oscillation frequency is below a lowest self-resonant frequency of the secondary.

16. The method of claim 14, wherein the feedback connection comprises a voltage pulse feedback signal.

17. The method of claim 14, wherein the feedback connection comprises a comparator.

18. The method of claim 17, wherein the feedback connection further comprises an inverter coupled to an output of the comparator and operable to invert the feedback signal.

19. A current sensor, comprising:
a first transformer comprising a primary and a secondary, wherein the current sensor is operable to measure current in the primary;
a sensing circuit operable to detect a resonant frequency of the secondary, where the resonant frequency of the secondary changes with an amount of current present in the primary.

20. A method of sensing current, comprising:
detecting a resonant frequency of a secondary of a transformer, where the resonant frequency of the secondary changes with an amount of current in a primary of the transformer and is used to indicate the current in the primary.

21. A current sensor, comprising:
a first transformer comprising a primary and a secondary wound around a core, wherein the current sensor is operable to measure current in the primary; and
a sensing circuit operable to detect an impedance of the secondary, where the impedance of the secondary changes with an amount of current in the primary and is used to indicate the current in the primary.
